(19) United States
(12) Patent Application Publication
(10) Pub. No.: US 2020/0279830 A1
(43) Pub. Date: Sep. 3, 2020

(54) INTERLEAVED MULTI-LAYER REDISTRIBUTION LAYER PROVIDING A FLY-BY TOPOLOGY WITH MULTIPLE WIDTH CONDUCTORS

(71) Applicant: MERCURY SYSTEMS, INC., Andover, MA (US)

(72) Inventors: Seann AYERS, Phoenix, AZ (US); Leonard REEVES, Gilbert, AZ (US)

(21) Appl. No.: 16/289,190

(22) Filed: Feb. 28, 2019

(51) Int. Cl. H01L 25/065; H01L 23/552; H01L 23/538

(52) U.S. Cl. CPC H01L 25/0652; H01L 23/552; H01L 23/5381; H01L 2225/06537; H01L 23/5386; H01L 2225/0651; H01L 23/5383

(57) ABSTRACT

A redistribution assembly may have multiple layers. Each layer may include a signal conductor and a ground conductor. The width of the ground conductors may exceed the width of the signal conductors. In addition, the layers may be vertically positioned over each other to form the redistribution layer assembly. The conductors may be interleaved such that the ground conductor of a top layer is vertically positioned over the signal conductor for a bottom layer and the signal conductor of the top layer is positioned over the ground conductor of the bottom layer. Multi-layer redistribution layer assemblies may be used with stacks of dies in an IC package to create a fly-by topology that provides electrical continuity in the X, Y and Z dimensions.

### BACKGROUND

A redistribution layer (RDL) provides an extra metal conductive layer on an integrated circuit (IC) to make conductive pads available to other locations on the IC. Often times, the RDL makes input/output pads available at an edge location on the IC to facilitate completion of the electrical connection path by wire bonding to pins on the substrate of the IC.

FIG. 1 depicts an example of a RDL that is positioned on top of a die for an IC package. The integrated circuit 100 includes a die 102 that may have an optional backside coating 103. A bond pad 106 is formed of a conductive material, such as a conductive metal, on the die 102. A die passivation layer 104 is deposited on top of the die 102. A dielectric layer 108 is deposited over the die passivation layer 104. A RDL metal layer 110 is deposited on top of the first dielectric layer 108. The RDL metal layer 110 creates an electrically conductive path between the bond pad 106 and the solder ball 114. Thus, the RDL metal layer 110 helps to effectively move the bond pad 106 location from a less favorable location to a more favorable location where the solder ball 114 is located. A second dielectric layer 112 is deposited on top of the RDL metal layer 110.

### SUMMARY

In accordance with an aspect of an exemplary embodiment, a redistribution layer assembly includes a first layer having a signal conductor of a first width and a ground conductor of a second width that differs non-negligibly from the first width. The redistribution layer includes a second layer positioned vertically over the first layer. The second layer has a signal conductor of the first width and a ground conductor of the second width. The signal conductor of the second layer is positioned vertically over the ground conductor of the first layer, and the ground conductor of the second layer is positioned vertically over the signal conductor of the first layer. A dielectric layer separates the first layer from the second layer.

The first width of the ground conductor may exceed the second width of the ground conductor of the signal conductors by at least 30 percent or by at least 50 percent in some instances.

In accordance with another aspect of an exemplary embodiment, an integrated circuit package includes at least two dies vertically stacked on each other to form a first stack of dies. A redistribution layer assembly is positioned on each of the at least two dies. Each redistribution layer assembly includes a first layer having a signal conductor of a first width and a ground conductor of a second width that differs non-negligibly from the first width. Each redistribution layer assembly also includes a second layer positioned vertically over the first layer. The second layer has a signal conductor of the first width and a ground conductor of the second width. The signal conductor of the second layer is positioned vertically over the ground conductor of the first layer and the ground conductor of the second layer is positioned vertically over the signal conductor of the first layer. A dielectric layer separates the first layer from the second layer.

The integrated circuit package may include bond wires extending between the redistribution layer assemblies on respective dies to vertically interconnect the redistribution layer assemblies. The integrated circuit package may also include at least two dies vertically stacked on each other to form a second stack of dies. Moreover, the integrated circuit package may include a bridge redistribution layer for connecting the first stack with the second stack. The redistribution layer assemblies may have a fly by typology. Ground vias may be provided in the redistribution layer assemblies. The integrated circuit package may be a memory integrated circuit package. In particular, the integrated circuit package may be a dynamic random access memory integrated circuit package.

### BRIEF DESCRIPTION OF THE DRAWINGS

FIG. 1 depicts an example of a conventional redistribution layer (RDL).

FIG. 2A shows a partially exploded perspective view of a memory IC package deploying RDL assemblies in a fly by topology in an exemplary embodiment.

FIG. 2B shows a side perspective of the IC package of FIG. 2A.

FIG. 2C shows a side view of the IC package of FIGS. 2A and 2B.

FIG. 3A illustrates a cross sectional view of a multi-layer RDL assembly having interleaved signal and ground conductors.

FIG. 3B illustrates various layers that may be found in an RDL assembly of an exemplary embodiment.

FIG. 4A shows an exemplary plot comparing the near-end cross-talk of a interleaved multi-layer variable width RDL of an exemplary embodiment with the near-end cross-talk of a conventional non-interleaved two-layer RDL.

FIG. 4B is an exemplary plot comparing the far-end cross-talk between an interleaved multi-layer variable width RDL of an exemplary embodiment with the far-end cross-talk of a conventional non-interleaved two-layer RDL.

FIG. 5A is an exemplary plot illustrating a reduction in far-end cross-talk for an 8 gigabit DDR4 implementation for an exemplary embodiment.

FIG. 5B is an exemplary plot illustrating a reduction in far-end cross-talk for a 16 gigabit DDR4 implementation for an exemplary embodiment.

FIG. 6A is an exemplary plot illustrating a reduction in near-end cross-talk for an 8 gigabit DDR4 implementation for an exemplary embodiment.

FIG. 6B is an exemplary plot illustrating a reduction in near-end cross-talk for a 16 gigabit DDR4 implementation for an exemplary embodiment.

FIG. 7A is an exemplary plot illustrating a reduction in return loss for an 8 gigabit DDR4 return loss implementation for an exemplary embodiment.

FIG. 7B is an exemplary plot illustrating a reduction in return loss for a 16 gigabit DDR4 implementation for an exemplary embodiment.

FIG. 8 illustrates an example of a dual inline memory module that may be used with the exemplary embodiments.

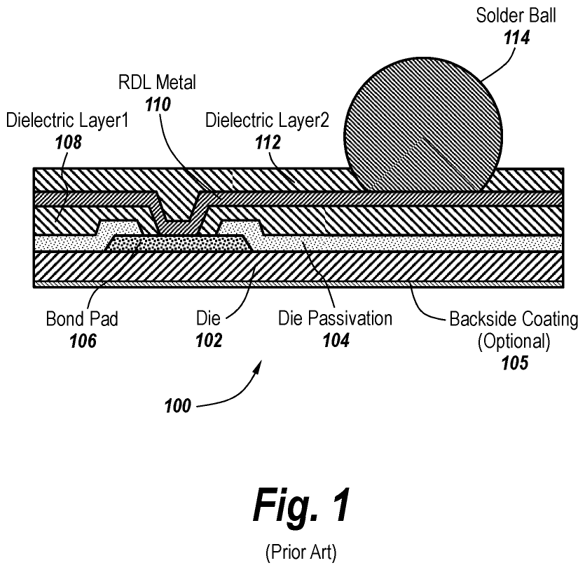

### DETAILED DESCRIPTION

IC's continue to operate faster and continue to have greater densities of components. One type of IC in which these trends are especially evident is in memory IC's. Memory IC products, such as double data rate 3 and 4 (DDR3 and DDR4) random access memory (RAM) IC modules have seen a dramatic increase in memory capacity and speed relative to their predecessors. Many of the DDR3 and DDR4 IC packages are three dimensional in that they have stacks of dies that each hold banks of RAM memory.

One of the challenges encountered with such memory packages is satisfying signal and power integrity performance goals. In particular, cross-talk both near-end and far-end has become a particular challenge with such products. In addition, there have been challenges with return loss. These problems arise in attempting to craft an RDL design for such memory products.

Exemplary embodiments described herein, help to reduce the cross-talk and return loss issues by providing a multi-layer RDL design having variable width conductors and interleaving of conductors across the layers. The interleaving helps to reduce the return loss issues. The interleaving in combination with increasing the width of the ground traces helps to significantly reduce the cross-talk between dissimilar signals.

The exemplary embodiments may employ a fly by linear bus topology. This topology also achieves significant improvement in return loss by eliminating stubs and branches. Moreover, this topology reduces cross-talk by providing a continuous signal return current path and increased fringe field isolation. The exemplary embodiments provide a continuous signal path in the X, Y and Z dimensions.

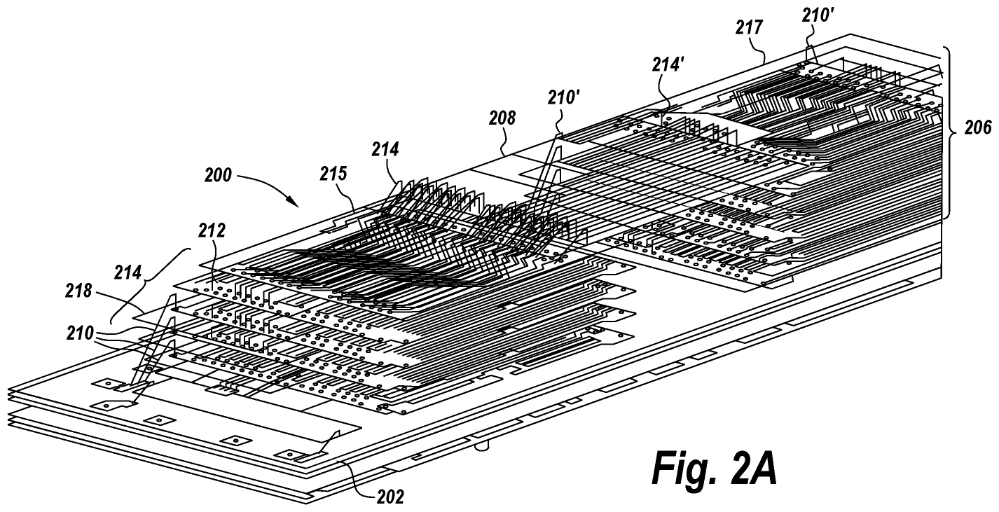

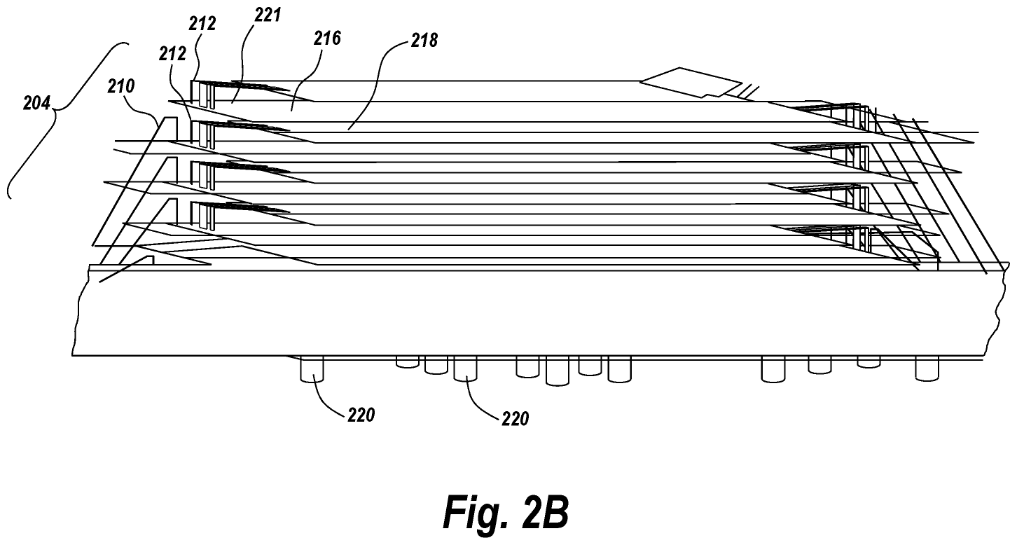

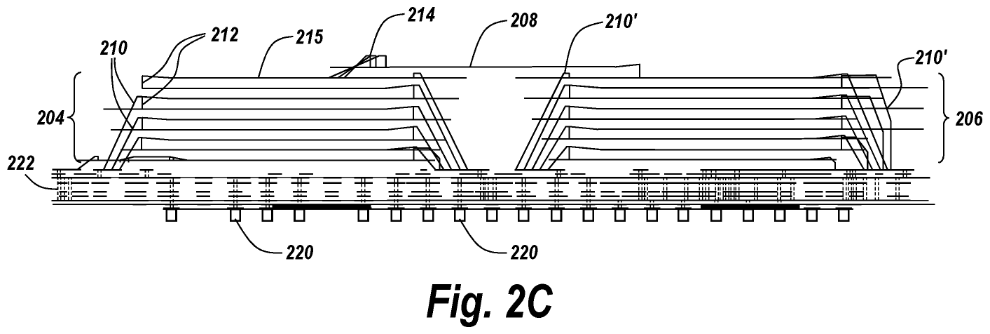

FIG. 2A shows an isometric partially exploded perspective view of an exemplary embodiment of an IC package. In the IC package 200 shown in FIG. 2A, there are two stacks 204 and 206 of nine dies each. The IC package 200 is a DDR4 memory package. Each die in the stack of dies 204 and 206 may hold memory banks. Each die has a separate RDL assembly for connecting the bond sites in the center of the die with sites on the edge of the die. The RDL layers are positioned on the top surface of the dies. The RDL layers are preferably formed from conductive metals, such as titanium, nickel or other suitable conductive metals.

As can be seen in FIGS. 2A, 2B and 2C, bond wires 210 connect the respective dies to elements on the substrate 202. Bond wires 212 also interconnect the respective dies that are adjacent to each other in a given die stack 204 or 206. The outside edges of the dies, such as die 218 are stepped to facilitate the connection of the bond wires to the die. As can be seen in the front view of FIG. 2C, there are nine dies in each stack 204 and 206. The second stack 206, has corresponding bond wires 210′ connecting the layers with the electrical components on the substrate 202. There is a 19^{th} die on the bridge 208 layer that connects the two stacks 204 and 216. As can be seen in FIGS. 2A, 2B and 2C, the first stack 204 is connected to the top layer 215 of the first stack is connected to the bridge layer 208 via bond wires 214. Similarly, bond wires 214′ connect the bridge layer 208 with the top layer 217 of the second stack 206.

An RDL layer is present on each of the layers of the dies stacks 204 and 206. The RDL layer provides a fly by linear bus topology. The signal paths are continuous in the X, Y and Z dimensions (see the legend in FIG. 2A).

This topology largely eliminates stubs and branches. The removal of the stubs and branches as well as having the continuous signal return current path helps to substantially improve the performance in return loss.

FIG. 2B provides a good illustration of the two dies that are on the lower layers of the die stacks. For example, the second most top layer 221 of the first die stack 204 has two dies 216 and 218. All but one of the layers in each stack has two dies. FIG. 2B also shows the ball grid elements 220 that electrically connect the substrate to a module as will be described in more detail below. Furthermore, there are vias 222 that electrically connect elements to the ball grid array elements 220.

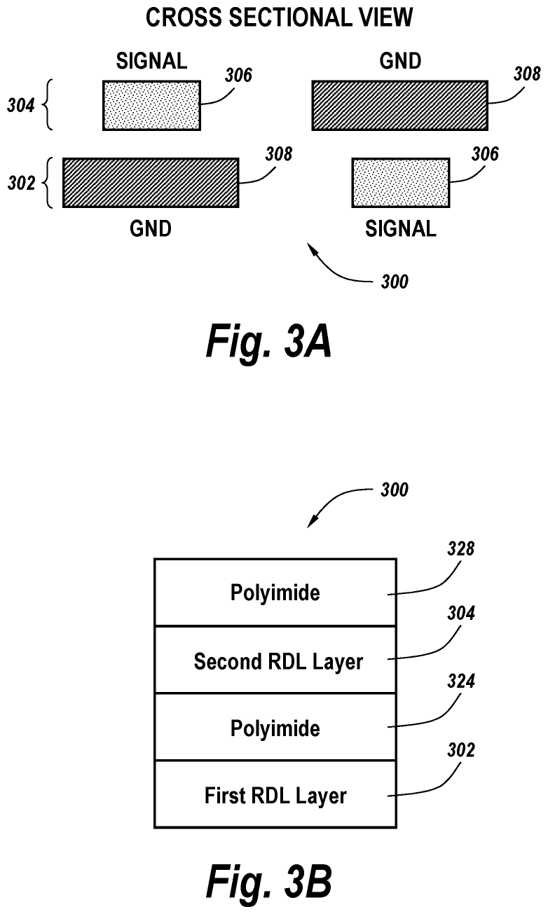

Each RDL assembly may include two layers, such as depicted in FIG. 3A. As shown in FIG. 3A from a cross sectional view of the RDL 300, a first layer 302 includes a signal trace conductor 306 and a ground trace conductor 308. These are positioned vertically (i.e., in the direction extending perpendicular upward from the substrate) below the second layer 304. The second layer 304, like the first layer 302, includes a ground trace conductor 308 and a signal trace conductor 306. The signal trace conductor 306 for the second layer 304 is positioned vertically above the ground trace conductor 308 for the first layer 302. Similarly, the ground trace conductor 308 of the second layer 304 is positioned vertically above the signal trace conductor 306 of the first layer 302. Thus, the signal ground trace conductors 306 and 308 are interleaved across the RDL layers 302 and 304. In addition, as shown in FIG. 3A, the ground trace conductor 308 is wider than the signal trace conductor 306. The ground trace conductors may be 30 percent wider than the signal trace conductors or even 50 percent wider than the signal trace conductors. In one implementation, the signal trace conductors are 14 microns wide whereas the ground trace conductors are 22 microns wide. Each RDL layer 302 and 304 may be 5 microns thick.

As shown in FIG. 3B, the RDL 300 includes the first RDL layer 304 on which a polyimide layer 324 is deposited. The second RDL layer 306 is positioned on top of the polyimide layer 324 and a final polyimide layer 328 is positioned on top of the first RDL layer 304.

The interleaving of the signal and ground traces 306 and 308 among the RDL layers helps to reduce the cross-talk and both the near-end and far-end. The widening of the ground traces 308 relative to the signal traces 306 also is helpful in maintaining signal integrity and reducing return loss. As will be discussed below, the vertical interleaving and increased of the ground trace width, significantly reduce the cross-talk and the unwanted fringe field coupling between dissimilar signals.

The architecture described above with the fly by topology, the interleaving and the increased width ground traces produces reductions in cross-talk and return loss.

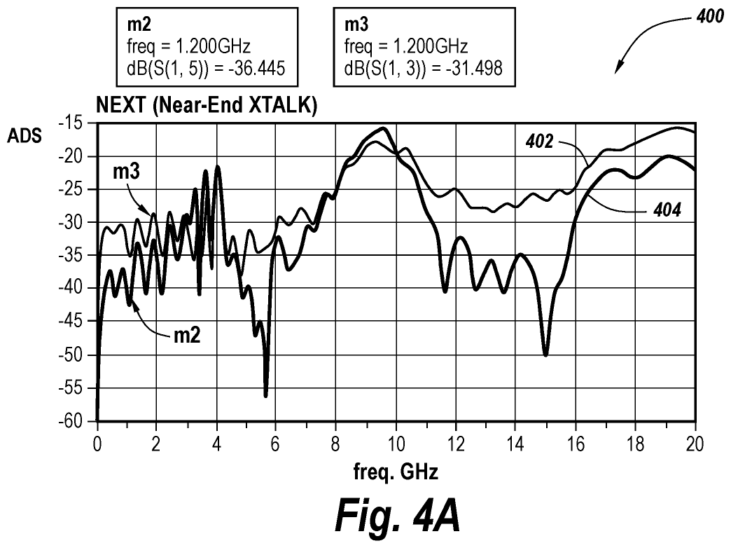

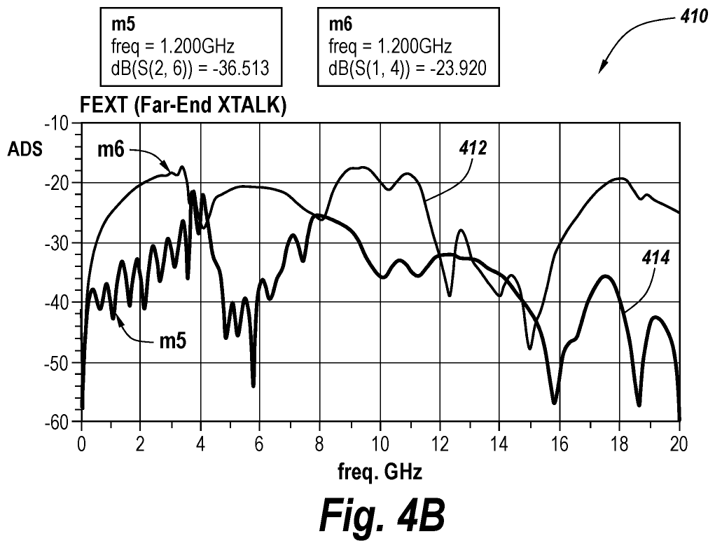

FIG. 4A illustrates a reduction in near-end cross-talk. The plot 400 shown in FIG. 4A depicts the near-end cross-talk magnitude in decibels across a frequency range for a conventional non-interleaved two-layer RDL implementation as captured by curve 404 versus an interleaved multi-layer variable width RDL like that of exemplary embodiments described herein as captured by a curve 402. As can be seen, the near-end cross-talk was improved by roughly 5 decibels.

FIG. 4B plots the same comparison relative to far-end cross-talk. The plot 410 shown in FIG. 4B shows the curve 414 for the conventional non-interleaved two-layer RDL versus the multi-layer variable width RDL of the exemplary embodiments as captured by curve 412. As can be seen, there is roughly a 15 decibels improvement in far-end cross-talk.

The improvement in cross-talk was also demonstrated for both an 8 gigabit DDR4 implementation and a 16 gigabit DDR4 implementation.

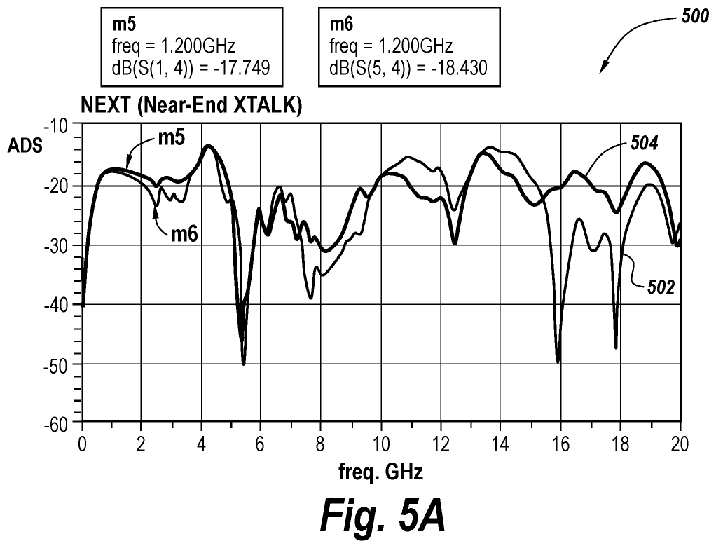

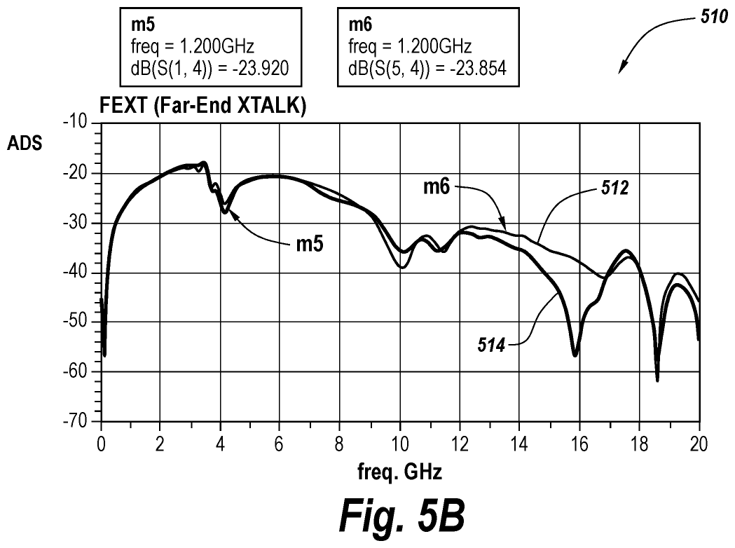

FIG. 5A depicts a plot 500 for the 8 gigabit DDR4 implementation. Curve 502 is for the conventional two-layer non-interleaved RDL, and curve 504 is for the interleaved variable width multi-layer RDL as described above for an 8 gigabit DDR4 implementation. The plot 500 demonstrates about an 18 decibels improvement in producing the far-end cross-talk. In FIG. 5B, the plot 510 shows the curves 514 for the conventional two-layer non-interleaved RDL and curve 512 for the interleaved variable width multi-layer RDL implementation of the exemplary embodiments for a 16 gigabit DDR4 implementation. There is roughly a 24 decibels reduction in the far-end cross-talk.

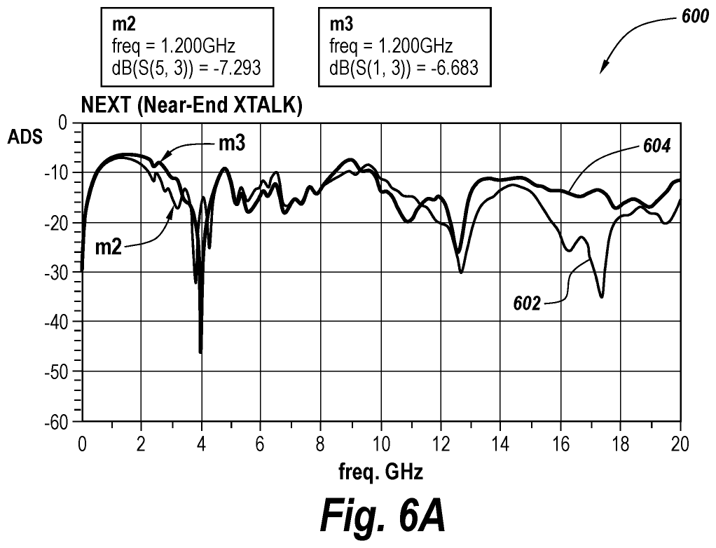

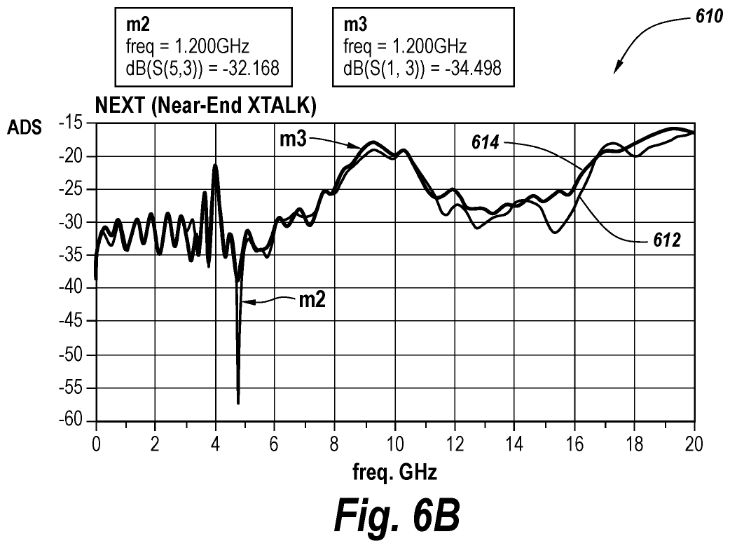

FIGS. 6A and 6B illustrate reduction in near-end cross-talk for an 8 gigabit DDR4 implementation and a 16 gigabit DDR4 implementation, respectively. As shown in FIG. 6A, the plot 600 has a curve 602 for the conventional two-layer non-interleaved RDL for an 8 gigabit DDR4 implementation and curve 604 for a interleaved variable width multi-layer RDL implementation for a 8 gigabit DDR4 implementation. There is roughly a 7 decibels improvement in the near-end cross-talk.

FIG. 6B shows a plot 610 with corresponding curve 612 and 614 showing a 32 decibels improvement in near-end cross-talk for a 16 gigabit DDR4 implementation.

The exemplary embodiments may also improve return loss.

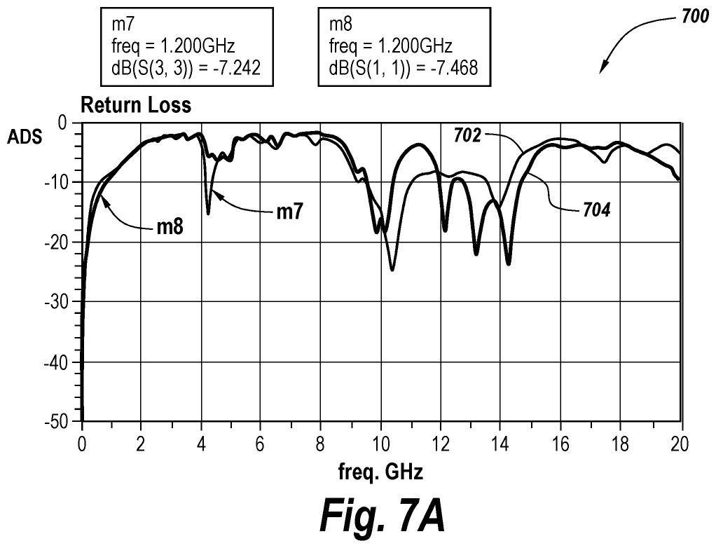

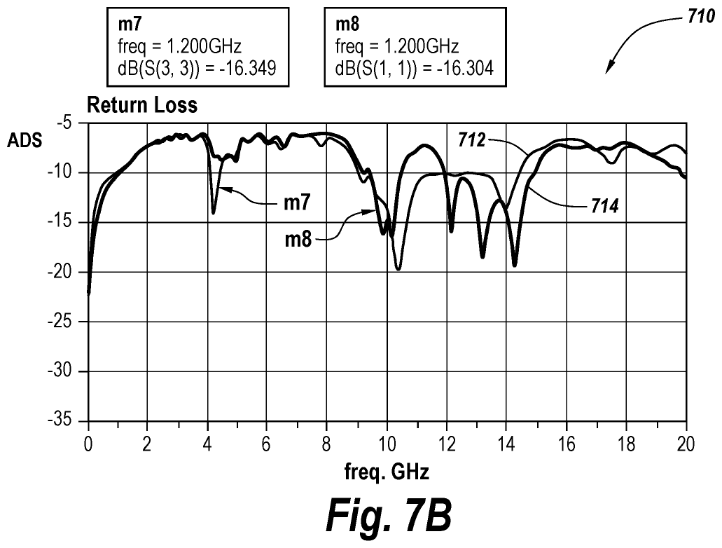

FIG. 7A shows a plot 700 relating to differences in return loss for an 8 gigabit DDR4 implementation. Curve 704 is for the conventional two-layer non-interleaved RDL, and curve 702 is for the multi-layer interleaved variable width RDL implementation of exemplary embodiments described above. The plot 700 demonstrates an improvement in the return loss of about 7.2 decibels.

FIG. 7B shows a plot 710 with similar data to FIG. 7A but for a 16 gigabit DDR4 implementation. Curve 712 is for the conventional two-layer non-interleaved RDL and curve 714 is for two-layer interleaved RDL implementation and curve 714 is for the interleaved multi-layer variable width RDL implementation of the exemplary embodiments described herein. The plot demonstrates improvement of approximately 16 decibels in return loss.

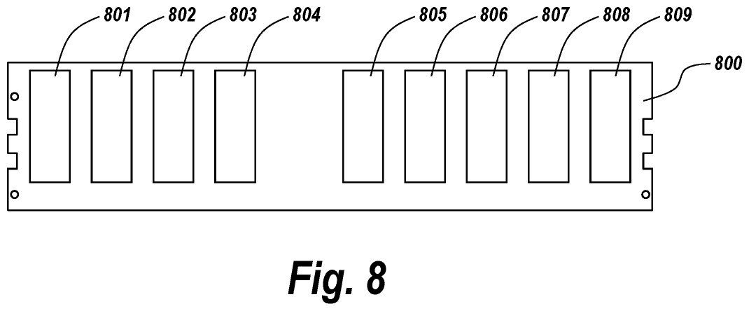

The IC packages described above may be part of a multi-chip module such as dual inline module 800 shown in FIG. 8 that includes chips 801-809. Each of these chips may be have an architecture like that described above. This is just one of many possible implementations for the memory module. Moreover, the IC packages described above need not be part of such a multi-chip module but may, in some embodiments, be part of a single chip package that stands alone.

While the present invention has been described with reference to exemplary embodiments herein, those skilled in the art will appreciate the various changes in form and detail may be made without departing from the intended scope of the present invention as defined in the claims that follow.

What is claimed as new and desired to be protected by Letters Patent of the United States is:

1. A redistribution layer assembly comprising:
a first layer having a signal conductor of a first width and a ground conductor of a second width that differs non-negligibly from the first width;
a second layer positioned vertically over the first layer, the second layer having a signal conductor of the first width and a ground conductor of the second width, wherein the signal conductor of the second layer is positioned vertically over the ground conductor of the first layer and the ground conductor of the second layer is positioned vertically over the signal conductor of the first layer; and
a dielectric layer separating the first layer from the second layer.

2. The redistribution layer assembly of claim 1, wherein the first width of the ground conductors exceeds the second width of the signal conductors by at least 30%.

3. The redistribution layer assembly of claim 2 wherein the first width of the ground conductors exceeds the second width of the signal conductors by at least 50%.

4. An integrated circuit package, comprising:
at least two dies vertically stacked on each other to form a first stack of dies; and
a redistribution layer assembly positioned on each of the at least two dies, wherein each redistribution layer assembly comprises:
a first layer having a signal conductor of a first width and a ground conductor of a second width that differs non-negligibly from the first width;
a second layer positioned vertically over the first layer, the second layer having a signal conductor of the first width and a ground conductor of the second width, wherein the signal conductor of the second layer is positioned vertically over the ground conductor of the first layer and the ground conductor of the second layer is positioned vertically over the signal conductor of the first layer; and
a dielectric layer separating the first layer from the second layer.

5. The integrated circuit package of claim 4, further comprising bond wires extending between the redistribution layer assemblies to vertically interconnect the redistribution layer assemblies.

6. The integrated circuit package of claim 4, further comprising at least two dies vertically stacked on each other to form a second stack of dies.

7. The integrated circuit package of claim 4, further comprising a bridge redistribution layer for electrically connecting the first stack with the second stack.

8. The integrated circuit package of claim 4, wherein the redistribution layer assemblies have a fly by topology.

9. The integrated circuit package of claim 4, further comprising ground vias in the redistribution layer assemblies.

10. The integrated circuit package of claim 4, wherein the integrated circuit package is a memory integrated circuit package.

11. The integrated circuit package of claim 4, wherein the integrated circuit package is a dynamic random access memory integrated circuit package.
